(19) United States
(12) Patent Application Publication
(10) Pub. No.: US 2025/0062196 A1
(43) Pub. Date: Feb. 20, 2025

(54) SEMICONDUCTOR DEVICE AND METHOD OF FORMING COMPONENTS FOR SEMICONDUCTOR DEVICE

(71) Applicant: Vishay Sillconix, LLC, San Jose, CA (US)

(72) Inventors: Lim CHEE CHIAN, Sitiawan (MY); Tuang KWANG HWEE, Serdang (MY); Yew-Khuan TEOH, Sungai Siput (MY); Barry LIN, Kaohsiung (TW); Stanley LAI, Taipei City (TW)

(73) Assignee: Vishay Silliconix LLC, San Jose, CA (US)

(21) Appl. No.: 18/720,247

(22) PCT Filed: Dec. 17, 2021
(86) PCT No.: PCT/US2021/064135

§ 371 Date: Jun. 14, 2024

(51) Int. Cl. H01L 23/495

(52) U.S. Cl. CPC H01L 23/49562; H01L 23/49503; H01L 23/49524

(57) ABSTRACT

A semiconductor device and method of forming semiconductor components is disclosed herein. In one aspect, the semiconductor components are formed from a common lead frame in which a die attach pad and a source clip are initially connected to each other. Formation of the semiconductor can either include cutting the source clip from the die attach pad and then stacking a die therebetween, or folding the source clip over the die attach pad such that the source clip is folded over a die attached to the die attach pad.

### FIELD OF INVENTION

The present disclosure relates to semiconductors, and is more particularly related to semiconductors, connection components for semiconductors, and formation techniques and methods for forming components of a semiconductor.

### BACKGROUND

Semiconductors are well known. One such known semiconductor is shown in FIG. 1A, which includes a die 2, such as a power MOSFET die, having a first surface (i.e. bottom surface) comprising a drain surface or contact, and a second surface (i.e. top surface) that includes a first metallized region defining a source contact 3 and a second metallized region comprising a gate contact 4. The semiconductor also includes a bottom metal plate 6 that is both coupled to and electrically connected to the drain contact. The semiconductor includes drain terminals 7 that extend from the bottom metal plate 6 and that are electrically connected to the drain contact. Source terminals 8 are electrically connected to the source contact 3 via electrical connections, such as wires 9, and a gate terminal 11 is electrically connected to the gate contact 4 via another electrical connection or wire 9. FIG. 1B shows another semiconductor arrangement in which a metal plate or a metal clip 12 replaces the wires 9. This configuration is considered an improvement over the arrangement of FIG. 1A due to the reduction in manufacturing time and costs associated with connecting the various wires 9 in FIG. 1A.

One common manufacturing process for power semiconductor packages involves creating a first lead frame to form the semiconductor die and associated leads, and creating a second lead frame to form the metal plate or clip. The two lead frames are completely distinct from each other.

There are problems associated with such manufacturing processes of forming semiconductor components from multiple lead frames due to excessive scraps or waste material that are generated based on known techniques and cutting patterns. It is generally undesirable to generate excessive waste while forming semiconductor components due to the associated increased costs and tooling efforts required. Further, known techniques involve a multi-step process in forming the component parts of the semiconductor devices.

### SUMMARY

A semiconductor device and method of forming semiconductor components are disclosed herein. In one aspect, the semiconductor components are formed from a common lead frame in which a die attach pad and a source clip are initially connected to each other. The common lead frame may comprise a continuous conductive material. Formation of the semiconductor can either include cutting the source clip from the die attach pad and then stacking a die therebetween, or folding the source clip over the die attach pad such that the source clip is also folded over a die attached to the die attach pad.

In one aspect, a semiconductor device is disclosed herein that includes a die attach pad connected at a first position to a source clip by a first source clip connecting bar, and connected at a second position to a gate clip by a gate clip connecting bar. A die is positioned on the die attach pad, and the semiconductor device also includes a source lead and a gate lead. The source clip is bent over at least a portion of the die attach pad such that at least a portion of the source clip provides electrical contact between at least a portion of the die and the source lead. The gate clip is bent over at least a portion of the die attach pad such that at least a portion of the gate clip provides electrical contact between at least a portion of the die and the gate lead.

In another aspect, a semiconductor device is disclosed herein that includes a die attach pad comprising a first portion of a source clip connection bar, and a first portion of a gate clip connection bar. A source clip comprises a second portion of the source clip connection bar. A gate clip comprises a second portion of the gate clip connection bar. A die is positioned on the die attach pad. The semiconductor device includes a source lead and a gate lead. The source clip is positioned over at least a portion of the die attach pad such that at least a portion of the source clip provides electrical contact between at least a portion of the die and the source lead. The gate clip is positioned over at least a portion of the die attach pad such that at least a portion of the gate clip provides electrical contact between at least a portion of the die and the gate lead.

A method of forming semiconductor components from a lead frame is also disclosed herein. The method can include providing a lead frame comprising a conductive material. The method can include machining the lead frame to form: a first die attach pad and a second die attach pad, a source clip connected to the first die attach pad by at least a first source clip connecting bar and connected to the second die attach pad by a second source clip connecting bar, a gate clip connected to the die attach pad by a gate clip connecting bar, a source lead, and a gate lead.

Additional aspects and embodiments are disclosed herein.

### BRIEF DESCRIPTION OF THE DRAWINGS

A more detailed understanding may be had from the following description, given by way of example in conjunction with the accompanying drawings, wherein like reference numerals in the figures indicate like elements, and wherein:

FIG. 1A is a top view of a semiconductor package according to the prior art.

FIG. 1B is a top view of another semiconductor package according to the prior art.

FIG. 2 is top view of a lead frame defining a plurality of rows and columns of semiconductor components.

FIG. 3A is a top view of a portion of a lead frame defining semiconductor components according to a first aspect.

FIG. 3B is a top view of the semiconductor components removed from the lead frame of FIG. 3A in a partially assembled state and prior to bending of a source clip and a gate clip.

FIG. 3C is a perspective view of the semiconductor components of FIG. 3B showing the source clip and the gate clip in unbent states in phantom lines and in bent states in solid lines.

FIG. 3D is a top view of the semiconductor components of FIGS. 3B and 3C in a partially assembled state.

FIG. 3E is a perspective view of the semiconductor components of FIGS. 3B-3D in a partially assembled state.

FIG. 3F is another perspective view of the semiconductor components of FIGS. 3B-3E in a partially assembled state.

FIG. 3G is a perspective view of the semiconductor components of FIGS. 3B-3F with an encapsulation.

FIG. 4A is a top view of a portion of a lead frame defining semiconductor components according to another aspect.

FIG. 4B is a perspective view of one subset of semiconductor components in a partially assembly state after being removed from the lead frame in FIG. 4A.

FIG. 4C is a perspective view of the semiconductor components of FIG. 4B.

FIG. 4D is a perspective view of the semiconductor components of FIGS. 4B and 4C with a die applied to a die attach pad.

FIG. 4E is a perspective view of the semiconductor components of FIGS. 4B-4D after being cut and stacked with each other.

FIG. 4F is another perspective view of the semiconductor components of FIGS. 4B-4E.

FIG. 4G is a top view of the semiconductor components of FIGS. 4B-4F.

FIG. 4H is a top view of another subset of semiconductor components from FIG. 4A in a cut and stacked configuration.

FIG. 4I is a perspective view of the semiconductor components of FIGS. 4B-4G with an encapsulation.

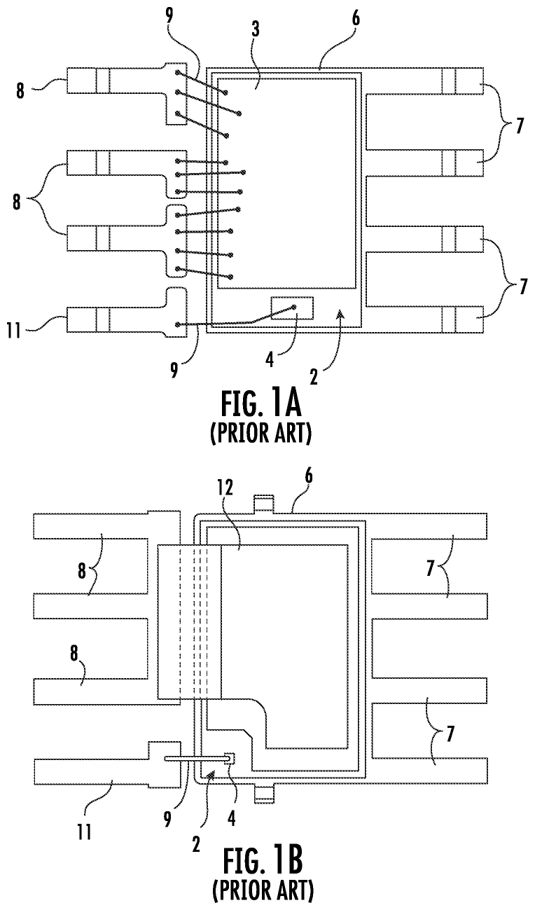

### DETAILED DESCRIPTION

Examples of different semiconductor implementations will be described more fully hereinafter with reference to the accompanying drawings. These examples are not mutually exclusive, and features found in one example can be combined with features found in one or more other examples to achieve additional implementations. Accordingly, it will be understood that the examples shown in the accompanying drawings are provided for illustrative purposes only and they are not intended to limit the disclosure in any way. Like numbers refer to like elements throughout.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element such as a layer, region, substrate, lead, clip, pad, or contact is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. It will be understood that these terms are intended to encompass different orientations of the element in addition to any orientation depicted in the figures.

Relative terms such as “below” or “above” or “upper” or “lower” or “horizontal” or “vertical” may be used herein to describe a relationship of one element, layer or region to another element, layer, region, substrate, lead, clip, pad, or contact as illustrated in the figures. It will be understood that these terms are intended to encompass different orientations of the device in addition to the orientation depicted in the figures.

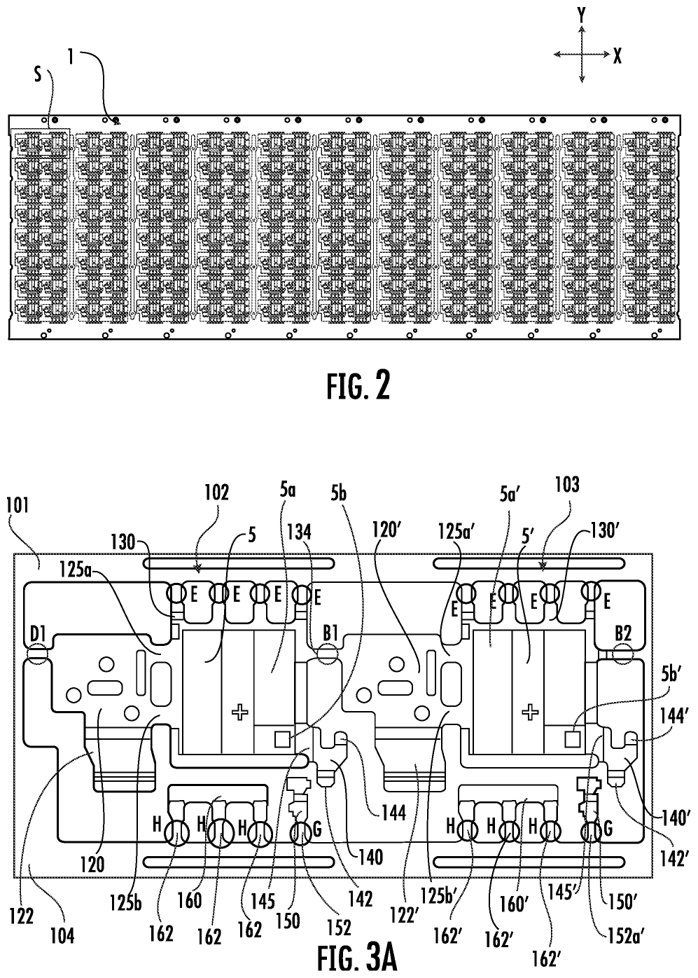

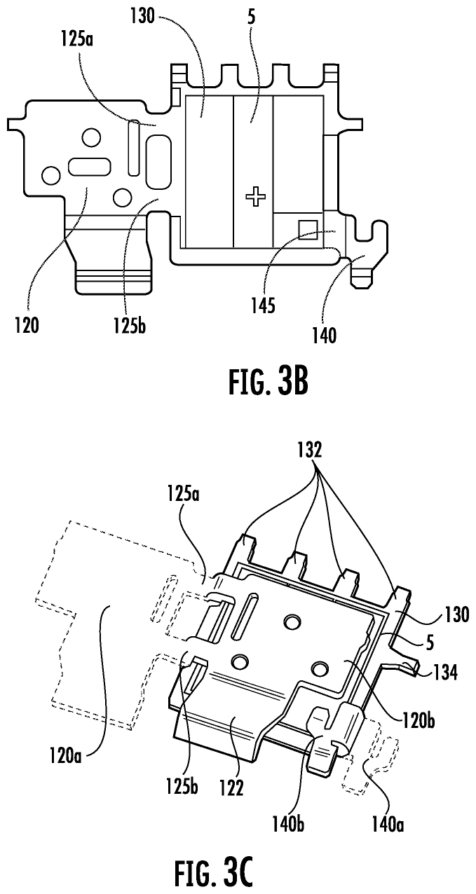

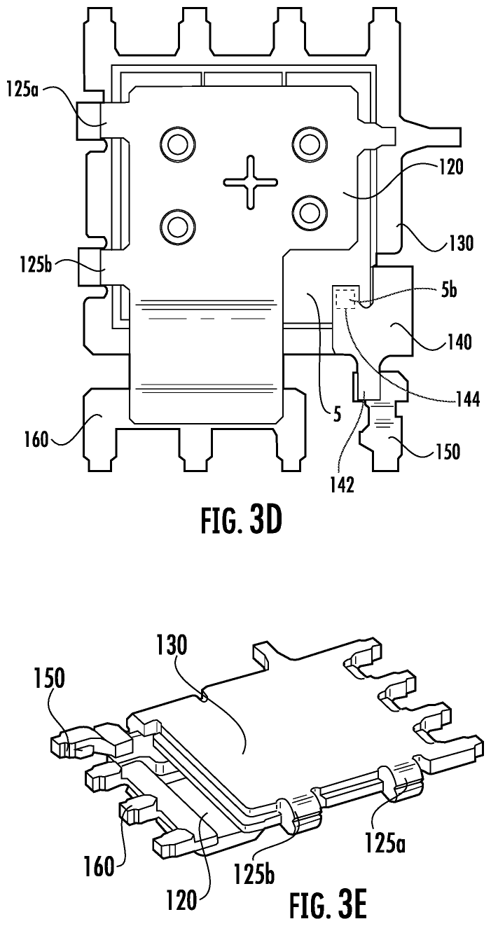

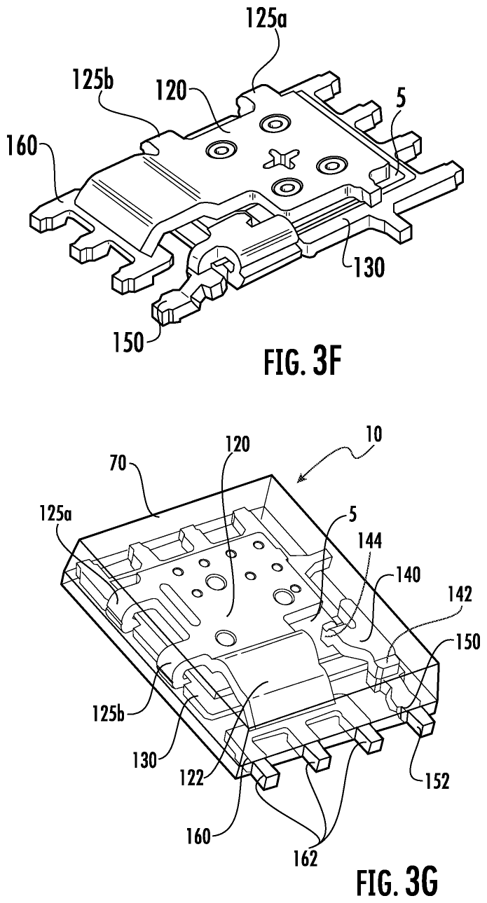

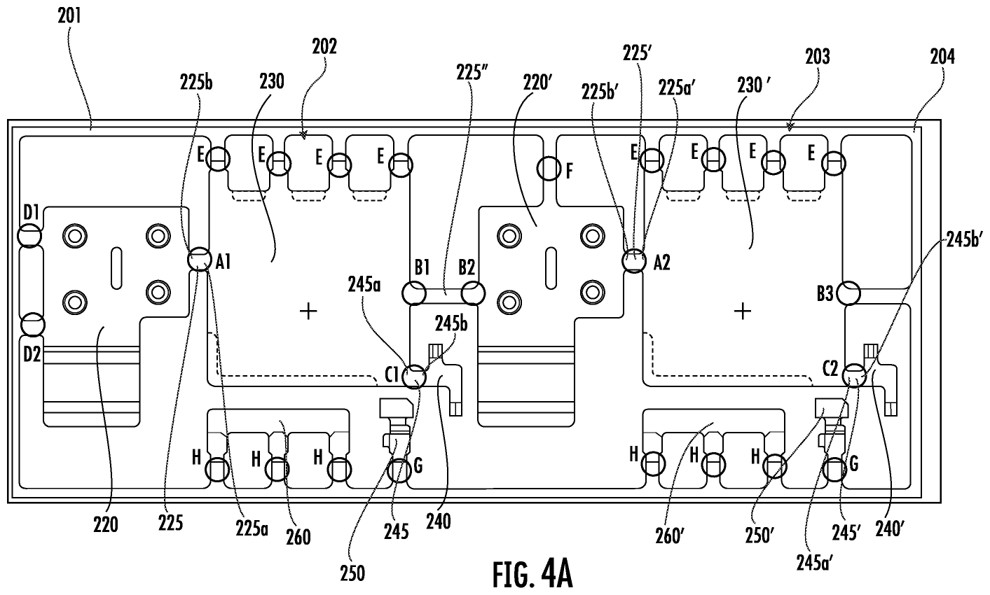

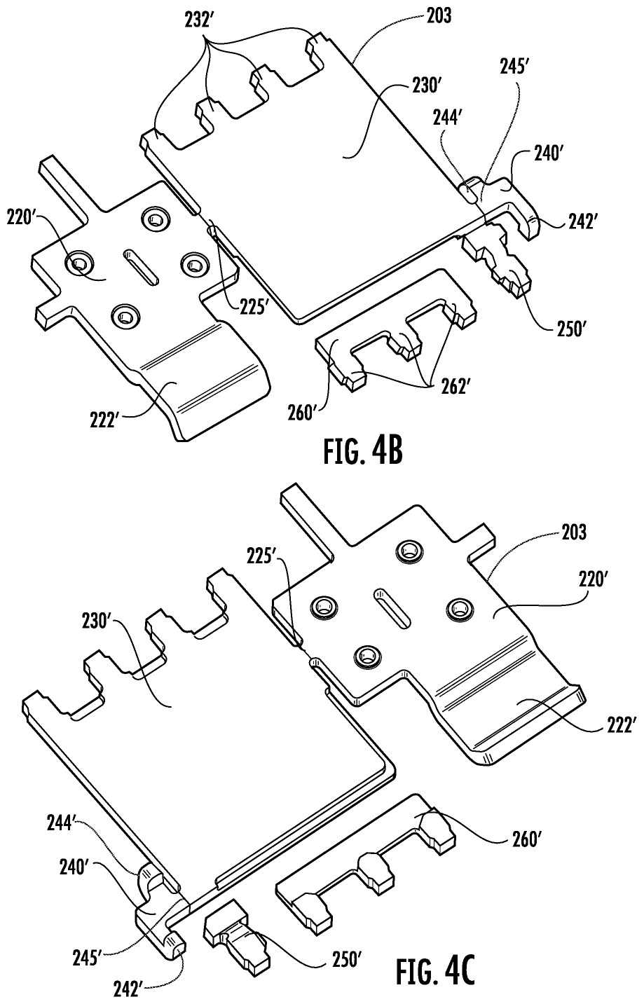

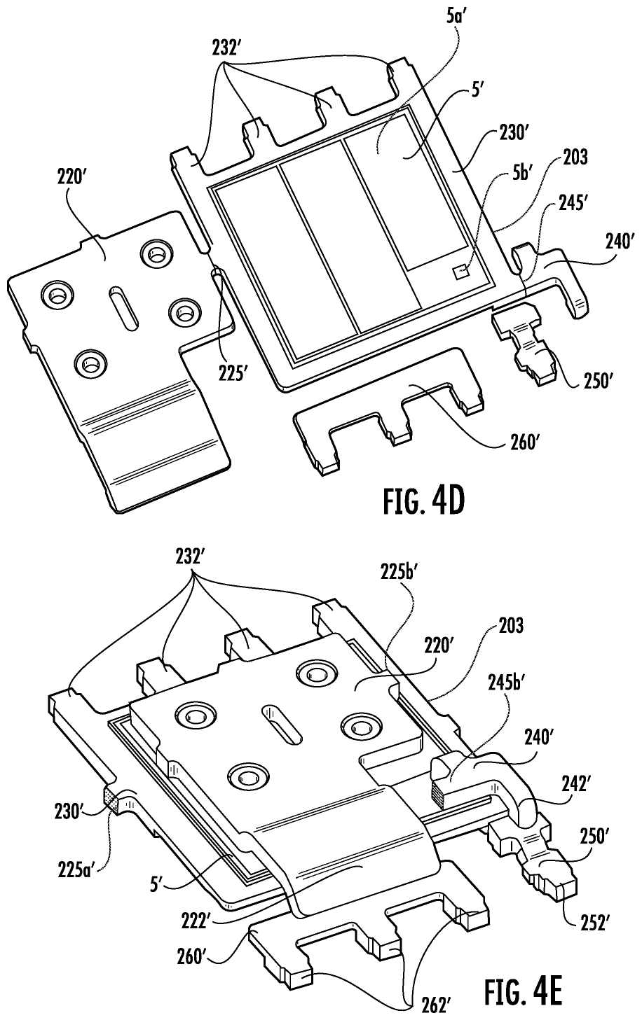

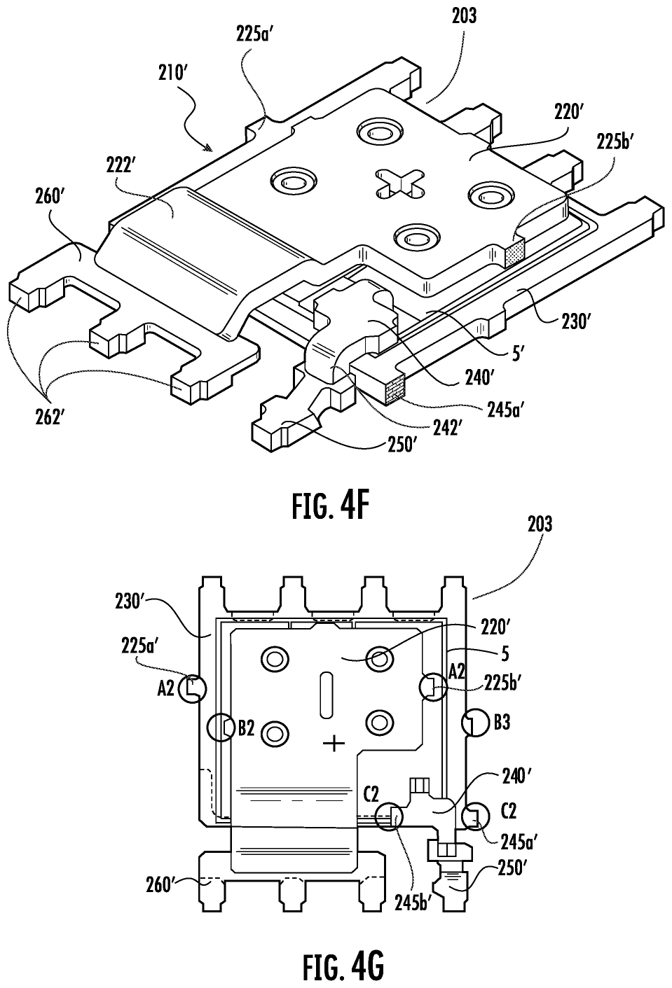

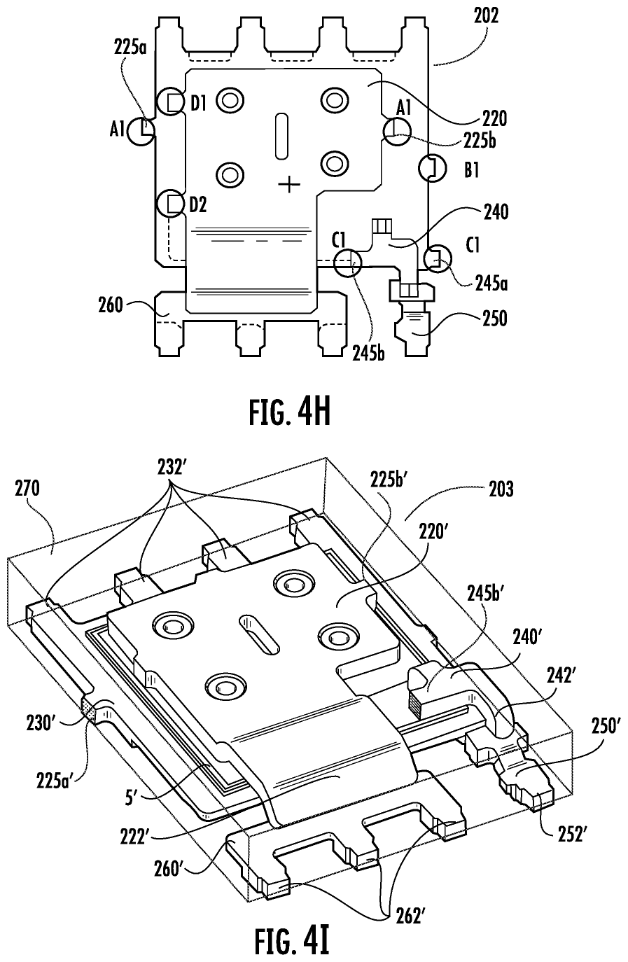

FIG. 2 illustrates a lead frame 1 with a plurality of rows (defined in the X-direction) and columns (defined in the Y-direction) of partially formed components. As shown in FIG. 2, the lead frame 1 has been machined to punch out the general shapes for the components such as a source clip (i.e. elements 120, 120′), die attach pad (i.e. elements 130, 130′), gate clip (i.e. elements 140, 140′), gate lead (i.e. elements 150, 150′), and source lead (i.e. elements 160, 160′). Area “S” is shown in FIG. 2 to illustrate an exemplary area containing a pair or group, i.e. a first and second, of source clips 120, 120′, die attach pads 130, 130′, gate clips 140, 140′, gate leads 150, 150′, and source leads 160, 160′. Area “S” generally corresponds to the portion of the lead frame shown in FIG. 3A, which are described in more detail herein. One of ordinary skill in the art would understand that a similar lead frame configuration could be provided for the semiconductor elements shown in FIG. 4A.

Based on the configuration of the lead frame 1 such as shown for example in FIG. 2, the present disclosure reduces steps in manufacturing, and material scraps during machining. Additionally, a high yield of semiconductor components is provided by the configuration shown in FIG. 2. For example, in the particular lead frame 1 of FIG. 2, 176 “units” are provided based on having eight distinct rows, eleven distinct columns, and a pair of units within each row and column. As used in this context, the term unit refers to a subset or package of semiconductor components including a source clip, die attach pad, gate clip, gate lead, and source lead. By forming all of the semiconductor metal materials from a single lead frame, there is a reduction in the requisite number of production lines associated with the components.

Referring to FIGS. 3A and 4A, various configurations for a lead frame 101, 201 including multiple types of semiconductor components are disclosed. In any of these aspects, the semiconductor components can be configured such that: (i) the semiconductor components are completely cut or detached from each other and subsequently layered or stacked to form a semiconductor, or (ii) the semiconductor components are attached to each other and can be bent over each other to provide electrical contacts and form a semiconductor. One of ordinary skill in the art would understand that in any of the configurations shown in FIGS. 3A and 4A, the resulting semiconductor could be formed from either stacked or layers components or folded components.

In FIGS. 3A and 4A, the lead frame 101, 201 is generally punched to define space between the various semiconductor components. As shown in FIGS. 3A and 4A, the lead frames 101, 201 are punched to define die attach pads 130, 130′, 230, 230′, source clips 120, 120′, 220, 220′, gate clips 140, 140′, 240, 240′, source leads 160, 160′, 260, 260′, and gate leads 150, 150′, 250, 250′. After punching out excess material from around these components, the lead frame 101, 201 can be further machined to separate the components from the lead frame 101, 201. In one aspect, various cuts are made between adjacent components and the components are then assembled together to form a semiconductor. In another aspect, some adjoining or adjacent components are left attached to each other, and later bent during formation of the semiconductor. The configurations shown in FIGS. 3A-3G relate to a “folded” design, while the configuration shown in FIGS. 4A-4I relates to another design in which individual components are cut from each other and then layered or stacked. In each of the configurations shown in FIGS. 3A and 4A, there are pairs of the semiconductor components within a single portion or section of the lead frame 101, 201. In this respect, each of the configurations provide a “two in one” style clip frame or lead frame design.

FIG. 3A illustrates a portion of a lead frame 101 including a plurality of semiconductor components that have been formed thereon. The lead frame 101 is formed from a conductive material. Suitable materials for the lead frame 101 can include copper, or other suitable highly conductive materials. As shown in FIG. 3A, a first set 102 and a second set 103 of semiconductor components are connected to a common perimeter 104 of the lead frame 101. This configuration is also shown in FIG. 4A, which is discussed in more detail herein. FIGS. 3B-3F illustrate the various semiconductor components in a detached state. The semiconductor device 10 is shown in an assembled state in FIG. 3G.

Each of the components illustrated in FIGS. 3A-3F, such as die attach pads 130, 130′, source clips 120, 120′, gate clips 140, 140′, source leads 160, 160′, and gate leads 150, 150′, besides the die 5, 5′ discussed in further detail below, are formed from a single lead frame 101. Thus, these components are at least initially formed from a lead frame comprising a continuous, uninterrupted conductive material. The semiconductor components may include, among other components and elements, a first die attach pad 130 connected at a first position to a first source clip 120 by at least one first source clip connecting bar 125a, 125b, and connected at a second position on an opposite side of the first die attach pad 130 from the first position to a first gate clip 140 by a first gate clip connecting bar 145. Likewise, a second die attach pad 130′ is connected at a first position to a second source clip 120′ by at least one second source clip connecting bar 125a′, 125b′, and connected at a second position to a second gate clip 140′ by a second gate clip connecting bar 145′.

A semiconductor device 10 may comprise a first die 5 positioned on the first die attach pad 130. The first die 5 can be a MOSFET die, according to one aspect. The first die 5 includes a first portion 5a, which is also referred to as a source contact, that is configured to engage with the first source clip 120 once the first source clip 120 is folded over and connected to the first die 5, and a second portion 5b, which is also referred to as a gate contact, that is configured to engage with the first gate clip 140 once the first gate clip 140 is folded over. Likewise, a second die 5′ is positioned on the second die attach pad 130′. The second die 5′ includes a first portion 5a′, which is also referred to as a source contact, that is configured to engage with the second source clip 120′ once the second source clip 120′ is folded over and connected to the second die 5′, and a second portion 5b′, which is also referred to as a gate contact, that is configured to engage with the second gate clip 140′ once the second gate clip 140′ is folded over.

The semiconductor device 10 further comprises a source lead 160, 160′ and a gate lead 150, 150′. The gate clip 140, 140′ can include a first gate clip connection 142, 142′ and a second gate clip connection 144, 144′. In one aspect, the first gate clip connection 142, 142′ is configured to provide contact with the gate lead 150, 150′. The second gate clip connection 144, 144′ is configured to contact the second portion 5b, 5b′ of the die 5, 5′. The source lead 160, 160′ may comprise a plurality of source lead terminals 162, 162′. The gate lead 150, 150′ may include at least one gate lead terminal 152, 152′.

Referring to FIGS. 3A-3G, according to one aspect, the source clip 120, 120′ is configured to be bent over at least a portion of the die attach pad 130, 130′ such that at least a portion of the source clip 120, 120′ provides electrical contact between at least a portion of the die 5, 5′ and the source lead 160, 160′. In one aspect, a source clip flange 122, 122′ is configured to be bent into contact with the source lead 160, 160′. The source clip flange 122, 122′ can be formed as a bent flange or extension from the main body of the source clip 120, 120′. The gate clip 140, 140′ is configured to be bent over at least a portion of the die attach pad 130, 130′ such that at least a portion of the gate clip 140, 140′ provides electrical contact between at least a portion of the die 5, 5′ and the gate lead 150, 150′.

The source clip connecting bar 125a, 125b, 125a′, 125b′ can preferably comprise a curved portion between the die attach pad 130, 130′ and the source clip 120, 120′. In one aspect, the die attach pad 130, 130′, the source clip 120, 120′, and the source clip connecting bar 125a, 125b, 125a′, 125b′ are integrally formed. The source clip connecting bar 125a, 125b, 125a′, 125b′ can have a portion having a U, C or arc shape, in one aspect.

The gate clip connecting bar 145, 145′ comprises a curved portion between the die attach pad 130, 130′ and the gate clip 140, 140′. In one aspect, the die attach pad 130, 130′, the gate clip 140, 140′, and the gate connecting bar 145, 145′ are integrally formed. The gate clip connecting bar 145, 145′ can have a portion having a U, C or arc shape, in one aspect.

The source clip connecting bar 125a, 125b, 125a′, 125b′ can include two separately formed connecting bars with a first connecting bar 125a, 125a′ that connects the die attach pad 130, 130′ to the source clip 120, 120′ at a first position, and a second source clip connecting bar 125b, 125b′ that connects the die attach pad 130, 130′ to the source clip 120, 120′ at a second position spaced apart from the first position. In one aspect, the first connecting bar 125a, 125a′ and the second source clip connecting bar 125b, 125b′ can be arranged on the same side of the source clip 120, 120′.

As shown in FIG. 3C, different states for the source clip 120 and the gate clip 140 are illustrated. In FIG. 3C, an original configuration (i.e. non-bent configuration) for the source clip 120 is shown as element 120a in phantom lines, while a bent configuration is shown as element 120b in solid lines. In the bent configuration 120b, the source clip 120 is bent over the die attach pad 130 and into contact with the die 5, and more specifically into contact with the first portion 5a of the die 5. Similarly, in FIG. 3C, the gate clip 140 is illustrated in the unbent state as element 140a in phantom lines, and shown in the bent state as element 140b in solid lines. In the bent configuration, the gate clip 140 is bent over and into contact with the die 5, and more specifically into contact with the second portion 5b of the die 5.

As shown in FIG. 3G, an encapsulation material 70 is configured to encapsulate the die attach pad 130, the die 5, the source clip 120, the gate clip 140, at least a portion of the source lead 160, and at least a portion of the gate lead 150. FIG. 3G illustrates the semiconductor 10 in a formed state. Although the encapsulation material 70 is only shown in FIG. 3G around the first set 102 of semiconductor components, one of ordinary skill in the art would understand that encapsulation material would be provided around the second set 103 of semiconductor components as well to form another semiconductor.

Additional aspects of semiconductor components are disclosed and illustrated in FIGS. 4A-4I. As shown in FIG. 4A, there are two sets of semiconductor components, including a first set 202 and a second set 203, attached to a perimeter 204 of the lead frame 201. A first die attach pad 230 comprises a first portion 225a of a first source clip connection bar 225 and a first portion 245a of a first gate clip connection bar 245. A first source clip 220 comprises a second portion 225b of the first source clip connection bar 225. A first gate clip 240 comprises a second portion 245b of the first gate clip connection bar 245.

As shown in FIG. 4A, a connection region A1 is defined between the first portion 225a of the first source clip connection bar 225 and the second portion 225b of the first source clip connection bar 225. The connection region A1 can be cut during processing, which results in the first portion 225a of the first source clip connection bar 225 having an end face with a dimension matching a dimension of an end face of the second portion 225b of the first source clip connection bar 225. Referring to FIG. 4A, additional regions for cutting are also shown. For example, region A2 is defined between a second die attach pad 230′ and a second source clip 220′. A second source clip connection bar 225′ is defined between second die attach pad 230′ and the second source clip 220′. The connection region A2 is more specifically defined between a first portion 225a′ of the source clip connection bar 225′ and a second portion 225b′ of the source clip connection bar 225′. The end faces of the first and second portions 225a′, 225b′ have matching dimensions due to the cut that occurs at connection region A2. As used herein, dimension can refer to the size, shape, width, height, and/or area. Further, the first portions 225a, 225a′ of the source clip connection bars 225, 225′ may have an end face having a composition matching a composition of a respective end face of the second portions 225b, 225b′ of the source clip connection bars 225, 225′, in that both of the first portions 225a, 225a′ and the second portions 225b, 225b′ are originally cut from the same source clip connection bars 225, 225′. This aspect is visually represented by matching patterns shown on the end faces of elements 225a′ and 225b′ in FIGS. 4E, 4F, and 4I.

In a partially assembled state, shown in FIGS. 4E-4H, the end face of the first portion 225a, 225a′ of the source clip connection bar 225, 225′ faces a first direction, the end face of the second portion 225b, 225b′ of the source clip connection bar 225, 225′ faces a second direction, and the first direction is different than the second direction. The end face of the first portion 225a, 225a′ of the source clip connection bar 225, 225′ is configured to be positioned adjacent a first side of the semiconductor device, and the end face of the second portion 225b, 225b′ of the source clip connection bar 225, 225′ is configured to be positioned adjacent a second side of the semiconductor device.

As shown in FIG. 4A, a connection region C1 is defined between the first portion 245a of the first gate clip connection bar 245 and the second portion 245b of the first gate clip connection bar 245. The connection region C1 can be cut during processing, which results in the first portion 245a of the first gate clip connection bar 245 having an end face having a dimension matching a dimension of an end face of the second portion 245b of the first gate clip connection bar 245. Further, the first portion 245a of the first gate clip connection bar 245 may have an end face having a composition matching a composition of an end face of the second portion 245b of the first gate clip connection bar 245, in that both the first portion 245a and the second portion 245b are originally cut from the same first gate clip connection bar 245. A connection region C2 is defined between the second die attach pad 230′ and a second gate clip 240′. The connection region C2 is more specifically defined between the first portion 245a′ of the gate clip connection bar 245′ and the second portion 245b′ of the gate clip connection bar 245′. When assembled, the end face of the first portion 245a, 245a′ of the first gate clip connection bar 245 faces in a first direction, and the end face of the second portion 245b of the first gate clip connection bar 245 faces in second direction, and the first direction is different than the second direction. The end faces of the first and second portions 245a, 245b′ have matching dimensions due to the cut that occurs at connection region C2. Further, the first portions 245a, 245a′ of the gate clip connection bars 245, 245′ may have an end face having a composition matching a composition of an end face of the second portions 245b, 245b′ of the gate clip connection bars 245, 245′, in that both of the first portions 245a, 245a′ and the second portions 245b, 245b′ are originally cut from the same gate clip connection bars 245, 245′. This aspect is visually represented by matching patterns shown on end faces of the elements 245a′ and 245b′ in FIGS. 4E, 4F, and 4I.

Regions B1 and B2 correspond to regions for cutting the lead frame 201 to separate the first die attach pad 230 from the second source clip 220′. In one aspect, cutting in regions B1, B2 separates the first set 202 and second set 203 of semiconductor components from each other. Region B3 corresponds to a region for cutting the second die attach pad 230′ from the lead frame 201. Regions D1 and D2 correspond to regions for cutting the first source clip 220 from the lead frame 201.

In an assembled state, the source clips 220, 220′ are positioned over at least a portion of the die attach pads 230, 230′ such that at least a portion of the source clips 220, 220′ provides electrical contact between at least a portion of the die 5, 5′ and the source leads 260, 260′. The gate clips 240, 240′ are positioned over at least a portion of the die attach pads 230, 230′ such that at least a portion of the gate clips 240, 240′ provides electrical contact between at least a portion of the die 5, 5′ and the gate leads 250, 250′.

After cutting the lead frame 201 in the areas circled in FIG. 4A, separate die attach pads, source clips, gate clips, gate leads, and source leads are provided. FIGS. 4B and 4C illustrate components of the semiconductor prior to assembly with the die 5′. FIG. 4D illustrates components of the semiconductor after assembly with the die 5′. FIGS. 4E and 4F illustrate the second die attach pad 230′, the second source clip 220′, the second gate clip 240′, the second gate lead 250′, and the second source lead 260′ stacked with each other and assembled with the die 5′. FIG. 4H illustrates the first die attach pad 230, the first source clip 220, the first gate clip 240, the first gate lead 250, and the first source lead 260. Although not specifically illustrated in FIGS. 4A-4H, an encapsulation material is provided that encapsulates the die attach pads 230, 230′, dies 5, 5′, the source clips 220, 220′, the gate clip 240, 240′, at least a portion of the source leads 260, 260′, and at least a portion of the gate leads 250, 250′. An exemplary configuration for this encapsulation 270 is shown in FIG. 4I.

As shown in FIG. 3A, a source clip connecting bar 134 can be provided between the first die attach pad 130 and the second source clip 120′. FIG. 4A shows a similar configuration with a source clip connecting bar 225″ between the first die attach pad 230 and the second source clip 220′. Once these connecting bars are cut, the cut ends can define terminals. For example, terminals 132, 134, 232 are illustrated in the Figures as extending from the respective die attach pads, and terminals 162, 262′ are illustrated in the Figures as extending from the respective source leads. One of ordinary skill in the art would recognize that any one of the semiconductor components disclosed herein can include terminals, and the terminals can be provided in various configurations.

A method of forming a semiconductor device is disclosed herein. The method includes providing a lead frame 1, 101, 201, such as shown in FIGS. 2, 3A, and 4A, comprising a conductive material. The method includes machining the lead frame 1, 101, 201 to thereby form: a first die attach pad 130, 230 and a second die attach pad 130′, 230′. In one aspect, machining can include cutting, punching, or any other process that involves removing selective areas of material from the lead frame 1, 101, 201.

FIG. 3A illustrates the first and second die attach pad 130, 130′ formed on the lead frame 101. FIG. 4A illustrates the first and second die attach pad 230, 230′ formed on the lead frame 201. In addition to two die attach pads, the lead frames 101, 201 of FIGS. 3A and 4A each also include two source clips 120, 120′, 220, 220′, two gate clips 140, 140′, 240, 240′, two gate leads 150, 150′, 250, 250′, and two source leads 160, 160′, 260, 260′.

To remove the semiconductor components from the lead frame 201, cutting region D1 is shown in FIG. 3A between the source clip 120 and the lead frame 101, and cutting regions D1, D2 are shown in FIG. 4A between the source clip 220 and the lead frame 201. As shown in FIG. 3A, cutting region B1 is provided at a source clip connecting bar 134 between the second source clip 120′ and the first die attach pad 130. Cutting regions B1, B2 are shown in FIG. 4A to show exemplary cutting regions for separating the first die attach pad 230 from the second source clip 220′.

One of ordinary skill in the art would understand based on this disclosure that the cutting regions will vary depending on a particular punching profile used on the lead frames 101, 201. For example, cutting regions or areas for the die attach pads 130, 130′, 230, 230′ are illustrated as areas “E” throughout FIGS. 3A and 4A, cutting region or area for the source clip 220′ is illustrated as area “F” in FIG. 4A, cutting regions or areas for the gate leads 150, 150′, 250, 250′ are illustrated as areas “G” throughout FIGS. 3A and 4A, and cutting regions or areas for the source leads 160, 160′, 260, 260′ are illustrated as areas “H” throughout FIGS. 3A and 4A.

The method includes machining the lead frame 101, 201 to form a source clip, i.e. source clip 120, 220, connected to the first die attach pad, i.e. die attach pad 130, 230, by at least a first source clip connecting bar, i.e. source clip connecting bar 125, 225. FIG. 3A illustrates a source clip 120 connected to the first die attach pad 130 by at least one first source clip connecting bar 125a. In one aspect, FIG. 3A illustrates a second source connecting bar 125b connecting the source clip 120 and the first die attach pad 130. FIG. 4A illustrates a source clip 220 connected to the first die attach pad 230 by at least one source clip connecting bar 225. The second source clip 220′ is connected to the second die attach pad 230′ via a source clip connecting bar 225′, and the second source clip 220′ is connected to the first die attach pad 230 via a source clip connecting bar 225″. In this configuration, a single source clip 220′ is connected to two different die attach pads 230, 230′.

The method includes machining the lead frame 101, 201 to form a gate clip, i.e. gate clip 140, 140′, 240, 240′, connected to the die attach pad, i.e. die attach pad 130, 130′, 230, 230′, by a gate clip connecting bar, i.e. gate clip connecting bar 145, 145′, 245, 245′. FIG. 3A illustrates a gate clip 140, 140′ connected to the die attach pad 130, 130′ by a gate clip connecting bar 145, 145′. FIG. 4A illustrates a gate clip 240, 240′ connected to the die attach pad 230, 230′ by a gate clip connecting bar 245, 245′.

The lead frame 101, 201 is also machined to form a source lead, i.e. source leads 160, 160′, 260, 260′, and a gate lead, i.e. gate leads 150, 150′, 250, 250′. FIG. 3A illustrates two source leads 160, 160′ and two gate leads 150, 150′. FIG. 4A illustrates two source leads 260, 260′ and two gate lead 250, 250′. The method further includes attaching a die 5, 5′ to the die attach pad, such as die attach pads 130, 130′, 230, 230′.

The method can also include cutting the second source clip connecting bar, i.e. source clip connecting bars 225′, 225″. Referring to FIG. 4A, in one aspect, cutting the source clip connecting bar 225″ separates the source clip 220′ from the first die attach pad 230. Source clip connecting bar 134 in FIG. 3A could be cut according to one aspect of the method in order to separate a first set of semiconductor components 102 from a second set of semiconductor components 103 within a single lead frame 101.

The method can further include bending the source clip (i.e. source clips 120, 120′) over at least a portion of the die attach pad (i.e. die attach pads 130, 130′) such that at least a portion of the source clip (i.e. source clips 120, 120′) provides electrical contact between at least a portion of the die 5 and the source lead (i.e. source leads 160, 160′).

The method can further include bending the gate clip (i.e. gate clips 140, 140′) over at least a portion of the die attach pad (i.e. die attach pads 130, 130′) such that at least a portion of the gate clip (i.e. gate clips 140, 140′) provides electrical contact between at least a portion of the die 5, 5′ and the gate lead (i.e. gate leads 150, 150′).

One of ordinary skill in the art would understand that additional method steps can be included, such as additional cutting, bending, stacking, layering, etc.

It will be appreciated that the foregoing is presented by way of illustration only and not by way of any limitation. It is contemplated that various alternatives and modifications may be made to the described embodiments without departing from the spirit and scope of the invention. Having thus described the present invention in detail, it is to be appreciated and will be apparent to those skilled in the art that many physical changes, only a few of which are exemplified in the detailed description of the invention, could be made without altering the inventive concepts and principles embodied therein. It is also to be appreciated that numerous embodiments incorporating only part of the preferred embodiment are possible which do not alter, with respect to those parts, the inventive concepts and principles embodied therein. The present embodiment and optional configurations are therefore to be considered in all respects as exemplary and/or illustrative and not restrictive, the scope of the invention being indicated by the appended claims rather than by the foregoing description, and all alternate embodiments and changes to this embodiment which come within the meaning and range of equivalency of said claims are therefore to be embraced therein.

What is claimed is:

1. A semiconductor device comprising:
a die attach pad connected at a first position to a source clip by a first source clip connecting bar, and connected at a second position to a gate clip by a gate clip connecting bar;
a die positioned on the die attach pad;
a source lead; and
a gate lead;
wherein the source clip is bent over at least a portion of the die attach pad such that at least a portion of the source clip provides electrical contact between at least a portion of the die and the source lead; and
wherein the gate clip is bent over at least a portion of the die attach pad such that at least a portion of the gate clip provides electrical contact between at least a portion of the die and the gate lead.

2. The semiconductor device of claim 1, wherein the first source clip connecting bar comprises a curved portion between the die attach pad and the source clip.

3. The semiconductor device of claim 1, wherein the gate clip connecting bar comprises a curved portion between the die attach pad and the gate clip.

4. The semiconductor device of claim 1, wherein the die attach pad, the source clip, and the first source clip connecting bar are integrally formed.

5. The semiconductor device of claim 1, wherein the die attach pad, the gate clip, and the gate clip connecting bar are integrally formed.

6. The semiconductor device of claim 2, wherein the first source clip connecting bar has a portion having a U, C or arc shape.

7. The semiconductor device of claim 3, wherein the gate clip connecting bar has a portion having a U, C or arc shape.

8. The semiconductor device of claim 1, further comprising a second source clip connecting bar connecting the die attach pad to the source clip at a third position spaced apart from the first position.

9. The semiconductor device of claim 8, wherein the die attach pad, the source clip, and the second source clip connecting bar are integrally formed.

10. The semiconductor device of claim 8, wherein the second source clip connecting bar comprises a curved portion between the die attach pad and the source clip.

11. The semiconductor device of claim 10, wherein the second source clip connecting bar has a portion having a U, C or arc shape.

12. The semiconductor device of claim 11, wherein the first source clip connecting bar and the second source clip connecting bar are configured to hold the source clip in position.

13. The semiconductor device of claim 1, further comprising an encapsulation material encapsulating the die attach pad, the die, the source clip, the gate clip, at least a portion of the source lead, and at least a portion of the gate lead.

14. A semiconductor device comprising:
a die attach pad comprising a first portion of a source clip connection bar, and a first portion of a gate clip connection bar;
a source clip comprising a second portion of the source clip connection bar;
a gate clip comprising a second portion of the gate clip connection bar;
a die positioned on the die attach pad;
a source lead; and
a gate lead;
wherein the source clip is positioned over at least a portion of the die attach pad such that at least a portion of the source clip provides electrical contact between at least a portion of the die and the source lead; and
wherein the gate clip is positioned over at least a portion of the die attach pad such that at least a portion of the gate clip provides electrical contact between at least a portion of the die and the gate lead.

15. The semiconductor device of claim 14, wherein the first portion of the source clip connection bar has an end face having a dimension matching a dimension of an end face of the second portion of the source clip connection bar.

16. The semiconductor device of claim 15, wherein the end face of the first portion of the source clip connection bar faces a first direction, and the end face of the second portion of the source clip connection bar faces a second direction, and the first direction is different than the second direction.

17. The semiconductor device of claim 15, wherein the end face of the first portion of the source clip connection bar is positioned adjacent a first side of the semiconductor device, and the end face of the second portion of the source clip connection bar is positioned adjacent a second side of the semiconductor device.

18. The semiconductor device of claim 14, wherein the first portion of the gate clip connection bar has an end face having a dimension matching a dimension of an end face of the second portion of the gate clip connection bar.

19. The semiconductor device of claim 18, wherein the end face of the first portion of the gate clip connection bar faces a first direction, the end face of the second portion of the gate clip connection bar faces a second direction, and the first direction is different than the second direction.

20. The semiconductor device of claim 14, further comprising an encapsulation material encapsulating the die attach pad, the die, the source clip, the gate clip, at least a portion of the source lead, and at least a portion of the gate lead.

21. A method of forming a semiconductor device, comprising:
providing a lead frame comprising a conductive material; and
machining the lead frame to form:
a first die attach pad and a second die attach pad,
a source clip connected to the first die attach pad by at least a first source clip connecting bar and connected to the second die attach pad by a second source clip connecting bar,
a gate clip connected to the die attach pad by a gate clip connecting bar,
a source lead, and
a gate lead.

22. The method of claim 21, further comprising:
attaching a die to the second die attach pad;
cutting the second source clip connecting bar; and
bending the source clip over at least a portion of the die attach pad such that at least a portion of the source clip provides electrical contact between at least a portion of the die and the source lead.

23. The method of claim 22, further comprising:
bending the gate clip over at least a portion of the die attach pad such that at least a portion of the gate clip provides electrical contact between at least a portion of the die and the gate lead.
